(19) United States
(12) Patent Application Publication
(10) Pub. No.: US 2007/0253570 A1
(43) Pub. Date: Nov. 1, 2007

(54) Microphone System

(75) Inventors: Masaaki Fukumoto, Kanagawa (JP); Minoru Etoh, Kanagawa (JP)

Correspondence Address: CROWELL & MORING LLP;INTELLECTUAL PROPERTY GROUP, P.O. BOX 14300, WASHINGTON, DC, 20044-4300, US

(73) Assignee: NTT DoCoMo, Inc., Chiyoda-ku (JP)

(21) Appl. No.: 11/664,619

(22) PCT Filed: Dec. 7, 2005
(86) PCT No.: PCT/JP05/22443

§ 371 Date: Apr. 4, 2007

(30) Foreign Application Priority Data
Dec. 7, 2004 (JP) 2004-354427

(51) Int. Cl. H03B 29/00; H04R 3/00

(52) U.S. Cl. 381/71.12; 381/122

(57) ABSTRACT

To provide a small, inexpensive microphone system which can reduce extraneous vibration noise. The microphone system has a first microphone mechanism 1a which has a sound hole for introducing sound and a second microphone mechanism 1b which is enclosed without a sound hole. The first microphone mechanism 1a and the second microphone mechanism 1b have approximately the same inner structure and are coupled rigidly or formed integrally. The microphone system outputs a differential signal using either a processing circuit 7 which outputs differential signal based on output difference between the first microphone mechanism 1a and second microphone mechanism 1b or electrodes arranged in opposite directions.

### TECHNICAL FIELD

The present invention relates to a microphone system used for cellular phones, small microphones, and the like. More particularly, the present invention relates to a microphone system which can be implemented in a small size at low cost and is impervious to extraneous vibration noise.

### BACKGROUND ART

To suppress extraneous vibration noise, conventional microphone systems use techniques including those which involve having a microphone capsule covered with a rubber or other vibration insulator, using a learning noise cancellation mechanism such as an adaptive noise filter, or detecting vibration noise components with a vibration sensor installed specially in a microphone capsule and canceling them using an electric circuit.

For example, Patent Document 1 describes a microphone which can be incorporated easily into equipment and is less prone to wind noise and hop noise. The microphone comprises a microphone unit which has a sound hole-bearing surface in which a plurality of sound holes are formed and a diaphragm placed at the back of the sound hole-bearing surface; a porous filter element which has such a surface shape as to cover all the plurality of sound holes formed in the sound hole-bearing surface of the microphone unit and is fitted over the sound hole-bearing surface; a body which, being placed adjacent to closure plates, has a cylindrical structure with end faces closed by the closure plates; a cylindrical casing which supports the microphone unit in the cylindrical body by forming a cavity in conjunction with the sound hole-bearing surface of the microphone unit; and a sound hole group which communicates inner and outer parts of the cavity in the cylindrical casing.

Also, Patent Document 2 describes a super-directional microphone which has a high sound pickup S/N ratio and can reduce the effect of noise produced by sound sources near the microphone, machine vibration, and wind. The microphone consists of omnidirectional microphone units 1, 2, and 3 arranged on a straight line in such a way that spacing between unit 1 and unit 2 as well as spacing between unit 2 and unit 3 will be d. A first primary sound pressure gradient unidirectional microphone is obtained by subjecting an output signal of the unit 2 to a phase delay corresponding to the spacing d between the units and subtracting the resulting signal from an output signal of the unit 1. A secondary sound pressure gradient super-directional microphone is obtained by determining a difference signal between the output signals of the first and second unidirectional microphones. Low-frequency components of its output signal are added and outputted.

Patent Document 1: JP2004-297765A

Patent Document 2: JP05-168085A

### DISCLOSURE OF THE INVENTION

However, the conventional examples described above have problems. Specifically, even if the sound holes are covered with a sound insulator and the like, the effect of the sound insulator is reduced when the microphone is reduced in size. Also, the use of the differential signal due to phase lags between two microphone units placed at a distance cannot remove noise itself. Anyway, to implement the noise cancellation mechanism, a large-scale circuit is required, resulting in increased cost and power consumption. Besides, the vibration sensor itself is expensive and differs in vibration mode from the diaphragm of the microphone, requiring a complicated correction circuit. The present invention has been made in view of the above circumstances and has an object to provide a microphone system which can be implemented in a small size at low cost and is impervious to extraneous vibration noise.

To solve the above problems, according to claim 1, there is provided a microphone system, comprising: a first microphone mechanism which has a sound hole for introducing sound; and a second microphone mechanism which is enclosed without a sound hole, wherein the first microphone mechanism and the second microphone mechanism are coupled rigidly or formed integrally. With this configuration, the microphone mechanism (hereinafter referred to as a first capsule) which has a sound hole and microphone mechanism (hereinafter referred to as a second capsule) which has an enclosed structure without a sound hole are installed being coupled rigidly and differential signal of these is outputted. The first capsule outputs “target sound+extraneous vibration” and the second capsule outputs only “extraneous vibration”, and thus only “the target sound” is outputted as the differential signal. This eliminates the need for a sound insulator or complicated noise canceller circuit and makes it possible to implement a small, inexpensive microphone system.

According to claim 2, in the microphone system set forth in claim 1, the first microphone mechanism and second microphone mechanism have approximately the same inner structure. With this configuration, since the first capsule and second capsule have the same inner structure except for the presence or absence of a sound hole, it is possible to use inexpensive microphone mechanisms as vibration sensors, making it unnecessary to use expensive vibration sensors. Also, vibration characteristics of the vibration sensors can be brought close to those of the microphone itself, making it possible to suppress only vibration components without using a complicated correction circuit.

According to claim 3, in the microphone system set forth in claim 1, a diaphragm installed in the second microphone mechanism is thinner, weaker in tension, or made of softer material than a diaphragm installed in the first microphone mechanism. This configuration makes it possible to remove more vibration noise by correcting changes in vibration mode due to the presence or absence of a sound hole.

According to claim 4, in the microphone system set forth in claim 3, the diaphragm installed in the second microphone mechanism has a single or multiple through-holes or the diaphragm itself has a mesh structure. This configuration offers the same effect as claim 3.

According to claim 5, the microphone system set forth in claim 1 further comprises a differential circuit which outputs a differential signal based on output difference between the first microphone mechanism and the second microphone mechanism. With this configuration, the first capsule which has a sound hole and second capsule which has an enclosed structure without a sound hole are installed being coupled rigidly and their differential signal is outputted by the differential circuit. The first capsule outputs “target sound+extraneous vibration” and the second capsule outputs only “extraneous vibration”, and thus only “the target sound” is outputted as the differential signal. This eliminates the need for a sound insulator or complicated noise canceller circuit and makes it possible to implement a small, inexpensive microphone system.

According to claim 6, in the microphone system set forth in claim 1, both the first microphone mechanism and the second microphone mechanism comprise a diaphragm which receives external vibration and a back electrode which constitutes a microphone in conjunction with the diaphragm; output from the diaphragm of the first microphone mechanism and output from the back electrode of the second microphone mechanism are connected; and output from the back electrode of the first microphone mechanism and output from the diaphragm of the second microphone mechanism are connected. With this configuration, a differential signal can be generated without using an external differential circuit, making it possible to implement a more inexpensive microphone system.

According to claim 7, in the microphone system set forth in claim 1, both the first microphone mechanism and the second microphone mechanism comprise a diaphragm which receives external vibration and a back electrode which constitutes a microphone in conjunction with the diaphragm; and electret films installed on the back electrodes of the first microphone mechanism and the second microphone mechanism are charged in opposite directions. With this configuration, a differential signal can be generated without using an external differential circuit, making it possible to implement a more inexpensive microphone system.

According to claim 8, in the microphone system set forth in claim 1, both the first microphone mechanism and the second microphone mechanism comprise a diaphragm which receives external vibration and an electrode which constitutes a microphone in conjunction with the diaphragm; and if the first microphone mechanism has a back-mounted electrode, the second microphone mechanism has an electrode installed at the front, and conversely if the first microphone mechanism has a front-mounted electrode, the second microphone mechanism has an electrode installed at the back. This configuration gives the microphone system directivity as well as vibration noise resistance.

According to claim 9, in the microphone system set forth in claim 1, both the first microphone mechanism and the second microphone mechanism comprise a diaphragm which receives external vibration and an electrode which constitutes a microphone in conjunction with the diaphragm; and the first microphone mechanism has another sound hole on the side of the diaphragm which does not have the sound hole. This configuration gives the microphone system directivity as well as vibration noise resistance.

According to claim 10, there is provided a microphone system, wherein two microphone systems set forth in claim 1 with the same or different sound holes are placed back to back or adjacent to each other in such a way that the respective sound holes will face in opposite directions, the microphone system comprising a differential circuit which outputs a differential signal based on output difference between the two microphone systems. This configuration makes it possible to implement a multi-microphone system which has directivity as well as vibration noise resistance.

According to claim 11, there is provided a microphone system, comprising: a first microphone mechanism which has a sound hole for introducing sound; a second microphone mechanism which is enclosed without a sound hole; and a third microphone mechanism which has a sound hole, wherein the sound hole in the first microphone mechanism and the sound hole in the third microphone mechanism are placed in such a way as to face in opposite directions, the second microphone mechanism is placed between the first microphone mechanism and the third microphone mechanism, and the first, second, and third microphone mechanisms are either coupled rigidly or formed integrally, being placed back to back or adjacent to each other, the microphone system further comprises a first differential circuit which outputs a differential signal based on output difference between the first microphone mechanism and the second microphone mechanism, a second differential circuit which outputs a differential signal based on output difference between the third microphone mechanism and the second microphone mechanism, and a third differential circuit which outputs a differential signal based on output difference between the first differential circuit and the second differential circuit. This configuration makes it possible to implement a multi-microphone system which has directivity as well as vibration noise resistance.

As described above, in the microphone system according to the present invention, a microphone capsule (first capsule) which has a sound hole and microphone capsule (second capsule) which has an enclosed structure without a sound hole are installed being coupled rigidly and their differential signal is outputted. The first capsule outputs “target sound+extraneous vibration” and the second capsule outputs only “extraneous vibration”, and thus only “the target sound” is outputted as the differential signal. This eliminates the need for a sound insulator or complicated noise canceller circuit and makes it possible to implement the microphone system in a small size at low cost.

Also, by using the same inner structure for the first capsule and second capsule except for the presence or absence of a sound hole, it is possible to use inexpensive microphone mechanisms as vibration sensors, making it unnecessary to use expensive vibration sensors. Also, vibration characteristics of the vibration sensors can be brought close to those of the microphone itself, making it possible to suppress only vibration components without using a complicated correction circuit.

Also, by correcting changes in vibration mode due to the presence or absence of a sound hole, it is possible to remove more vibration noise.

Also, by a) connecting the first capsule and second capsule in parallel in opposite directions, b) charging the electret films of the first capsule and second capsule in opposite directions, or c) arranging the electrodes of the first capsule and second capsule in opposite directions, it is possible to generate a differential signal without using an external differential circuit, and thus to implement the microphone system at lower cost.

Also, by installing sound holes also at the back of the first capsule, it is possible to give directivity as well as vibration noise resistance.

Also, by installing microphone capsules in combination, it is possible to give directivity as well as vibration noise resistance. Specifically, it is possible to give directivity as well as vibration noise resistance a) by installing two sets of microphones according to the present invention next to each other and outputting their differential signal, or b) by installing a microphone capsule (first capsule) which has a sound hole, a microphone capsule (second capsule) which has an enclosed structure without a sound hole, and another microphone capsule (third capsule) which has a sound hole in such a way that the sound hole in the first capsule and the sound hole in the third capsule will face in opposite directions and that the first, second, and third capsules will be placed adjacent to each other or back to back and coupled rigidly and outputting a differential signal obtained from (first capsule minus second capsule) minus (third capsule minus second capsule). It is possible to give directivity as well as vibration noise resistance.

### BRIEF DESCRIPTION OF THE DRAWINGS

FIGS. 1A and 1B are diagrams showing a configuration of a microphone system according to a first embodiment of the present invention, where FIG. 1A is a perspective view and FIG. 1B is a sectional view;

FIG. 2 is a schematic diagram showing functions of the microphone system according to the first embodiment of the present invention;

FIGS. 3A to 3C are schematic diagrams showing diaphragm structures, where FIG. 3A shows an example in which multiple through-holes are provided, FIG. 3B shows an example in which a single through-hole is provided, and FIG. 3C shows an example of a mesh structure;

FIG. 4 is a diagram showing a circuit configuration example of the microphone system according to the first embodiment of the present invention;

FIG. 5 is a diagram showing another circuit configuration example of the microphone system according to the first embodiment of the present invention;

FIGS. 6A to 6C are diagrams showing circuit configuration examples of a microphone system according to a second embodiment of the present invention, where FIG. 6A shows a first circuit configuration, FIG. 6B shows a second circuit configuration, and FIG. 6C shows a third circuit configuration;

FIGS. 7A and 7B are diagrams showing the third circuit configuration of the microphone system according to the second embodiment of the present invention, where FIG. 7A is a sectional view and FIG. 7B is a circuit diagram;

FIGS. 8A and 8B are sectional views showing configurations of a microphone system according to a third embodiment of the present invention, where FIG. 8A shows a basic configuration and FIG. 8B shows another configuration;

FIGS. 9A and 9B are diagrams showing configurations of a microphone system according to a fourth embodiment of the present invention, where FIG. 9A is a schematic diagram and FIG. 9B is a perspective view showing another configuration; and

FIGS. 10A to 10C are diagrams showing configurations of a microphone system according to a fifth embodiment of the present invention, where FIG. 10A is a circuit diagram, FIG. 10B is a circuit diagram showing another configuration, and FIG. 10C is a perspective view showing still another configuration.

### BEST MODE FOR CARRYING OUT THE INVENTION

Microphone systems according to embodiments of the present invention will be described in detail below with reference to the drawings.

### First Embodiment

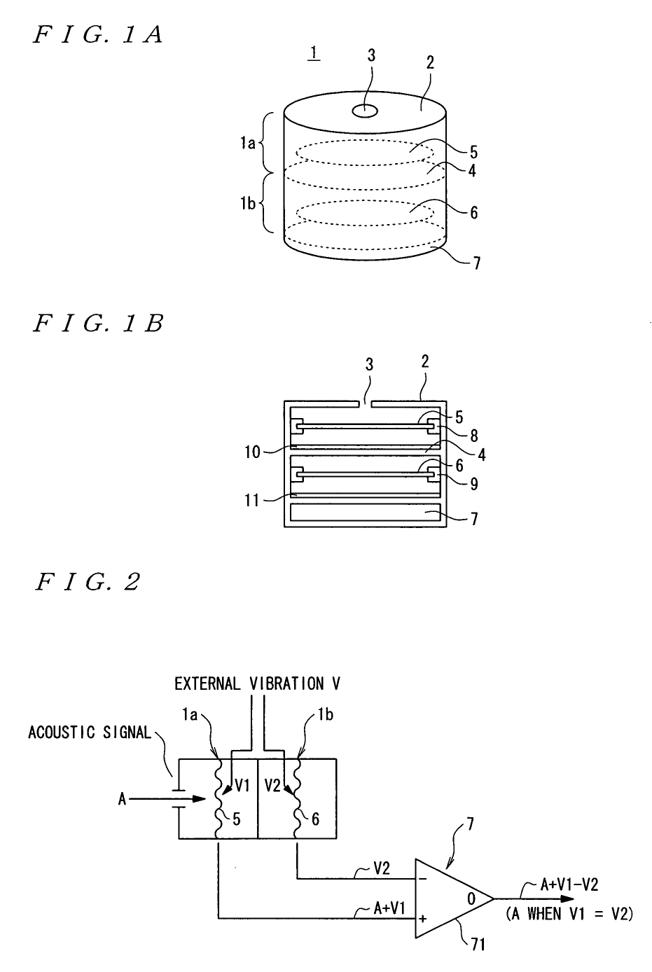

To begin with, a microphone system according to a first embodiment of the present invention will be described with reference to FIGS. 1A, 1B, 2, 3A to 3C, and 4.

FIGS. 1A and 1B are diagrams showing a configuration of the microphone system according to the first embodiment of the present invention, where FIG. 1A is a perspective view and FIG. 1B is a sectional view.

This embodiment is a microphone system of a basic type.

The microphone system 1 has a microphone capsule case 2 which has been formed into a cylindrical shape. A sound hole 3 which introduces sound is provided in an end face of the microphone capsule case 2, but no sound hole is provided in the other end face. The end face with the sound hole 3 will be referred to herein as a front face, and the other end face will be referred to as a back face. The microphone system 1 has a cylindrical shape as a whole, and its interior is divided into two compartments by a separator 4: a compartment with the sound hole 3 and a compartment enclosed without a sound hole. The compartment with the sound hole will be designated as a first microphone 1a and the compartment enclosed without a sound hole will be designated as a second microphone 1b. The first microphone 1a has a first diaphragm 5, first diaphragm support 8, and first back plate 10 while the second microphone 1b has a second diaphragm 6, second diaphragm support 9, and second back plate 11. Besides, the second microphone 1b has a processing circuit 7 at a predetermined location. Both the first microphone 1a and second microphone 1b have a microphone mechanism and are either coupled rigidly or formed integrally.

In the first microphone 1a, the first diaphragm 5 which is shaped like a disk is held by the first diaphragm support 8 installed on an inner wall of the microphone capsule case 2. Also, the first back plate 10 is installed parallel to the first diaphragm 5. An electret film (not shown) is installed on the first back plate 10, and the first diaphragm 5 and first back plate 10 work as an electret condenser microphone.

As against the first microphone 1a, the second microphone 1b occupies the remaining compartment of the microphone capsule case 2 divided by the separator 4. As is the case with the first microphone 1a, the second diaphragm 6 which is shaped like a disk is held by the second diaphragm support 9 installed on an inner wall of the microphone capsule case 2. Also, the second back plate 11 is installed parallel to the second diaphragm 6. An electret film (not shown) is installed on the second back plate 11, and the second diaphragm 6 and second back plate 11 work as an electret condenser microphone. Incidentally, the second microphone 1b is enclosed without a sound hole 3.

The processing circuit 7 accepts output from the first microphone 1a consisting of the first diaphragm 5 and first diaphragm support 8 as well as output from the second microphone 1b consisting of the second diaphragm 6 and second diaphragm support 9. Then it outputs a differential signal based on the difference between the outputs. That is, the processing circuit 7 generates and outputs a differential signal (signal from the first microphone minus signal from the second microphone) based on input signals from the first microphone 1a and second microphone 1b.

The sound hole 3 has an opening almost at the center of the front face of the first microphone 1a in the cylindrical microphone capsule case 2.

FIG. 2 is a schematic diagram showing functions of the microphone system according to the first embodiment of the present invention.

The first microphone 1a has the sound hole 3 as described above, and the first diaphragm 5 vibrates due to an acoustic signal A from outside as well as external vibration V1 resulting from external vibration V applied to the microphone capsule case 2 and transmitted through the first diaphragm support 8. Thus, an output signal of the first microphone 1a is (A+V1).

On the other hand, since the second microphone 1b is enclosed, the acoustic signal A from outside does not reach the second diaphragm 6 and the second diaphragm 6 vibrates only due to external vibration V2 resulting from external vibration V applied to the microphone capsule case 2 and transmitted through the second diaphragm support 9.

The processing circuit 7 finds signal difference between the first microphone 1a and second microphone 1b and outputs (A+V1−V2), which becomes A when V1 and V2 are equal. Thus, the target acoustic signal A alone can be extracted. To equalize V1 and V2, it is desirable to use the same structure and material for the first microphone 1a and second microphone 1b whenever possible.

More specifically, the first microphone 1a is perforated with a sound hole and the second microphone 1b is enclosed. Thus, even if the two microphones are of the same structure and material, the first diaphragm 5 of the first microphone 1a is subject to reduced damping effect of air and is more prone to vibration than the second diaphragm 6 of the second microphone 1b. Consequently, the first and second diaphragms 5 and 6 differ in sensitivity and frequency characteristics. To correct this, the second diaphragm 6 can be made more prone to vibration, for example, by reducing its thickness or tension or using a softer material compared to the first diaphragm 5.

This makes it possible to bring the two diaphragms close to each other in term of vibration characteristics and improve noise reduction performance.

Other possible methods include the following.

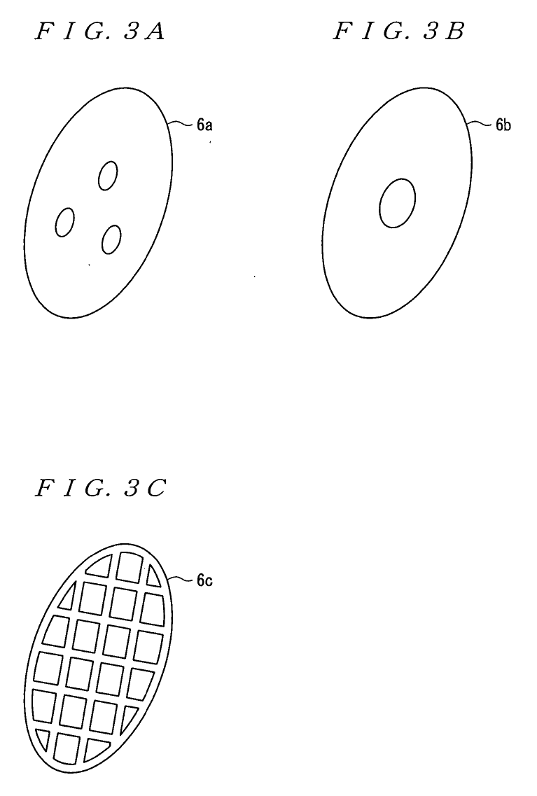

FIGS. 3A to 3C are diagrams showing diaphragm structures, where FIG. 3A shows an example in which multiple through-holes are provided, FIG. 3B shows an example in which a single through-hole is provided, and FIG. 3C shows an example of a mesh structure.

Available diaphragms include a diaphragm 6a obtained by producing multiple through-holes in the second diaphragm 6 as shown in FIG. 3A, a diaphragm 6b obtained by producing a single through-hole in the second diaphragm 6 as shown in FIG. 3B, and a diaphragm 6c obtained by giving a mesh structure with multiple holes to the second diaphragm 6 itself as shown in FIG. 3C.

In this way, by producing one or more holes in the second diaphragm 6, it is possible to communicate air chambers on both sides of the diaphragm, reducing the damping effect of air, and thereby increasing vibration proneness of the second diaphragm 6.

Also, by changing the locations, number, and size of the holes as well as mesh size or spacing, it is possible to control the magnitude of the damping effect, making it easier to make characteristics of the second diaphragm 6 match those of the first microphone 1a.

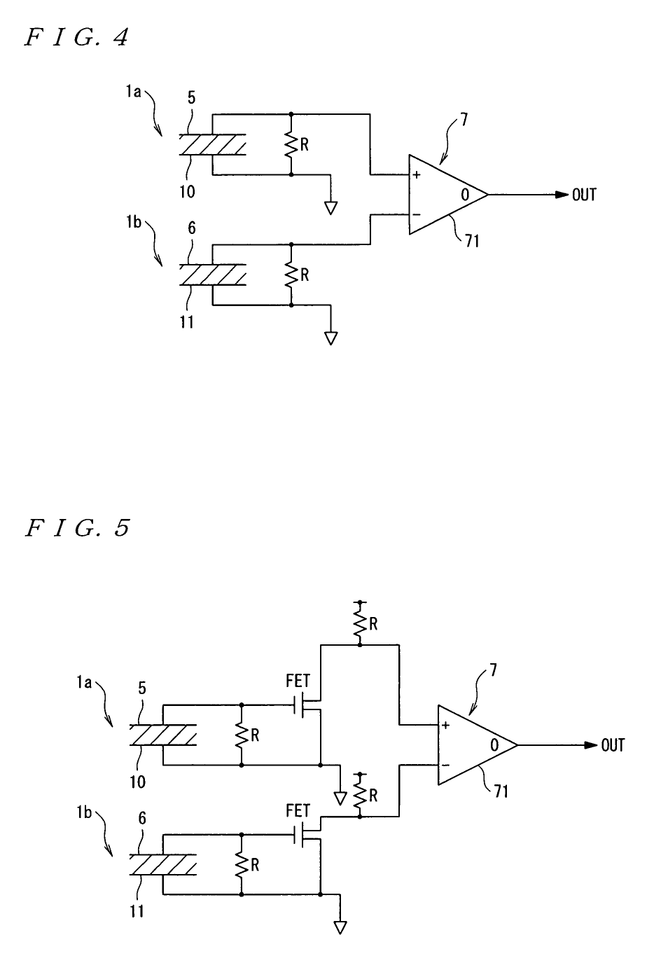

FIG. 4 is a first circuit configuration diagram (basic circuit configuration diagram) of the microphone system according to the first embodiment of the present invention.

As shown in FIG. 4, signals from the first microphone 1a and second microphone 1b are outputted through a differential circuit 71 of the processing circuit 7. The output from the first microphone 1a is entered in a positive input of the differential circuit 71 while the output from the second microphone 1b is entered in a negative input of the differential circuit 71. Then, the differential circuit 71 outputs a difference signal between the two outputs.

As described above, by using the same configuration for the compartments of the first microphone 1a and second microphone 1b except for the presence or absence of a sound hole 3, this embodiment provides good vibration suppression characteristics and makes it possible to use inexpensive constituent materials already used for microphones.

Incidentally, the first microphone 1a and second microphone 1b may differ in constituent materials as long as equivalent performance (V1=V2) can be obtained.

Also, this embodiment provides good vibration suppression characteristics by building both microphones into the hard microphone capsule case 2. In this way, it is desirable that the first microphone 1a and second microphone 1b are coupled rigidly, being placed as close to each other as possible.

Incidentally, it is not strictly necessary to place the first microphone 1a and second microphone 1b close to each other or couple them rigidly as long as equivalent performance can be obtained.

Although in this embodiment, electret films are used for the first back plate 10 and second back plate 11, electret films may also be used for the first diaphragm 5 and second diaphragm 6 (film electret type) or for the front plate which is an end face of the cylindrical shape. Besides, a condenser microphone without an electret film may also be used.

Furthermore, instead of a condenser microphone, a coil microphone or ribbon microphone can offer similar effect as long as it has a structure consisting of a first microphone (with a sound hole) and second microphone (enclosed without a sound hole).

Next, another circuit configuration example of the microphone system according to the first embodiment of the present invention will be described with reference to FIG. 5.

FIG. 5 is a second circuit configuration diagram of the microphone system according to the first embodiment of the present invention.

In this example, field effect transistors (FETs) for impedance conversion are installed in an input stage of the differential circuit 71 as shown in FIG. 5. In this example, a FET is installed both on the side of the first microphone 1a and on the side of the second microphone 1b. In this way, by amplifying voltage using field effect transistors, it is possible to increase resistance to external noise.

Incidentally, the processing circuit 7 may be installed outside the microphone capsule case 2, but to increase resistance to external noise, it is desirable to install the processing circuit 7 in a shielded state as close to the microphone capsule case 2 as possible.

Furthermore, to absorb the difference in vibration characteristics of the first microphone 1a and second microphone 1b, the output from the first microphone 1a or second microphone 1b may be passed through an equalizer or filter before differential processing.

### Second Embodiment

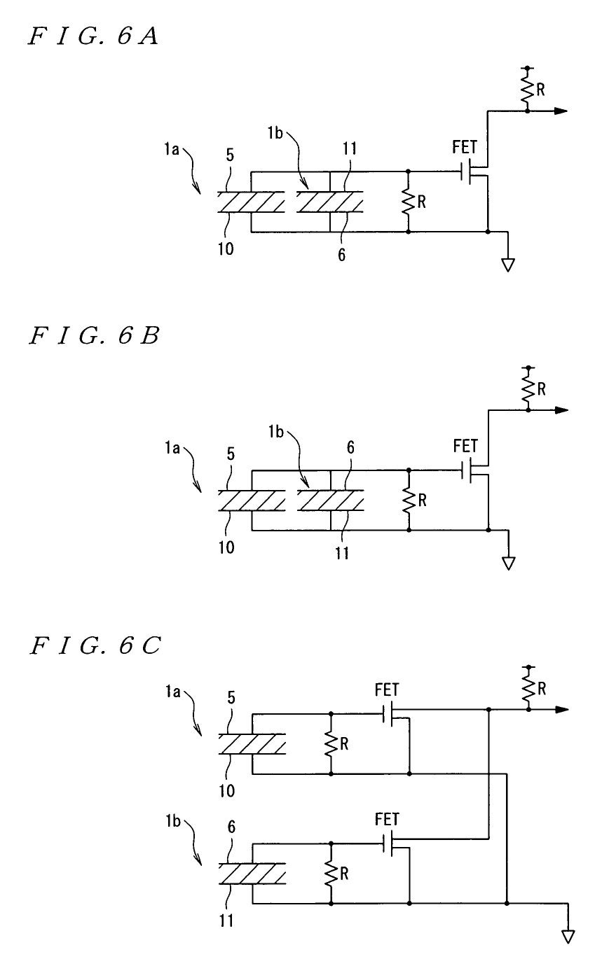

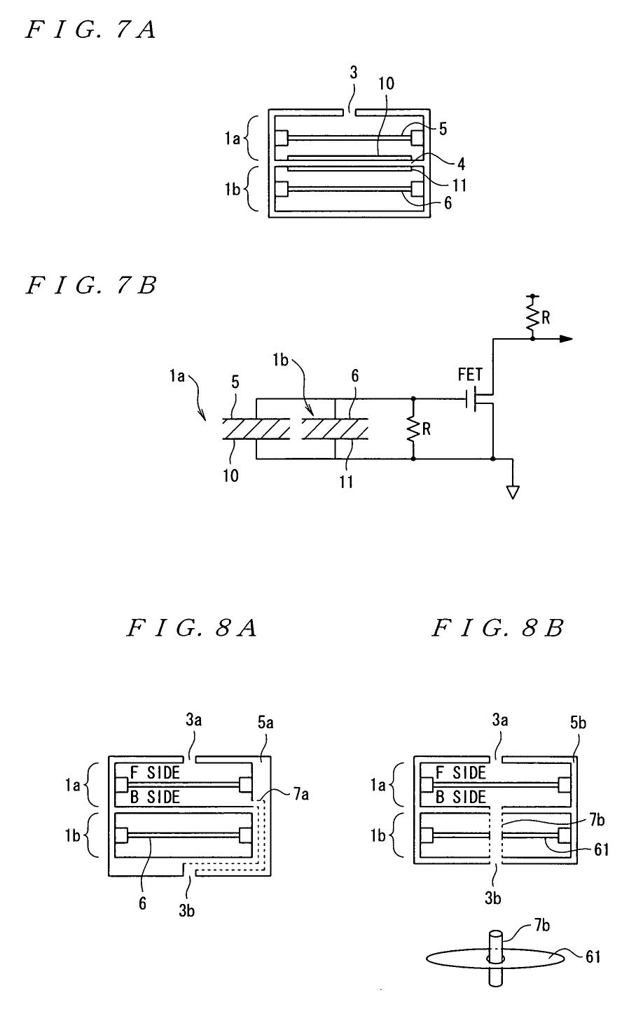

Next, a microphone system according to a second embodiment of the present invention will be described with reference to FIGS. 6A to 6C, 7A and 7B.

FIG. 6A is a first circuit configuration diagram of the microphone system according to the second embodiment of the present invention.

In this example, the first diaphragm 5 and first back plate 10 of the first microphone 1a are installed in the opposite direction to the second diaphragm 6 and second back plate 11 of the second microphone 1b. Thus, the first microphone 1a and second microphone 1b are connected in parallel but in opposite directions.” Consequently, only a difference signal between the first microphone 1a and second microphone 1b is outputted, eliminating the need for the differential circuit 71.

FIG. 6B is a second circuit configuration diagram of the microphone system according to the second embodiment of the present invention.

This circuit configuration has the same effect as the first circuit configuration described with reference to FIG. 6A. In this example, the first microphone 1a and second microphone 1b are connected in parallel in the “same direction.” However, the electret film of the second microphone 1b and electret film of the first microphone 1a are charged in opposite directions. This offers the same effect as when the first microphone 1a and second microphone 1b are connected in reverse polarity.

FIG. 6C is a third circuit configuration diagram of the microphone system according to the second embodiment of the present invention.

Incidentally, when the first microphone 1a and second microphone 1b produces outputs in opposite directions, the same effect can be obtained by using a single buffer FET for the two microphones as shown in FIGS. 6A and 6B or by installing a buffer FET for each microphone and combining the outputs as shown in FIG. 6C.

FIGS. 7A and 7B are diagrams showing the third circuit configuration of the microphone system according to the second embodiment of the present invention, where FIG. 7A is a sectional view and FIG. 7B is a circuit configuration diagram.

In this example, the first microphone 1a and second microphone 1b are connected in parallel in the same direction as shown in FIG. 7B. This is another circuit configuration example which has the same effect as the second processing circuit described with reference to FIG. 6B. However, contrary to the first microphone 1a, the second back plate 11 of the second microphone 1b is placed on the opposite side of the first back plate 10 via the separator 4, facing the front side of the second diaphragm 6 (side nearer to the sound hole 3) as shown in FIG. 7A. As a result, this offers the same effect as when the first microphone 1a and second microphone 1b are connected in reverse polarity.

The same effect can be obtained even when the first back plate 10 of the first microphone 1a is placed on the front side and the second back plate 11 of the second microphone 1b is placed on the back side conversely.

Incidentally, the electrodes of the first microphone 1a and second microphone 1b are placed in opposite directions (from front to back or from back to front) in FIGS. 7A and 7B. When they are placed in the same manner (e.g., both at the front or both at the back), the same effect can be obtained by placing one of the microphones front to back. Again, a circuit in which a separate buffer FET is installed for each microphone as shown in FIG. 6C is also available in addition to the circuit shown in FIG. 7B.

### Third Embodiment

Next, a microphone system according to a third embodiment of the present invention will be described with reference to FIGS. 8A and 8B.

FIGS. 8A and 8B are sectional views showing configurations of the microphone system according to the third embodiment of the present invention. FIG. 8A is a sectional view showing a basic configuration and FIG. 8B is a sectional view showing another configuration. This embodiment is a directional microphone system with a through-hole.

As shown in FIG. 8A, the microphone system according to this embodiment has a first sound hole 3a, second sound hole 3b, and a through-hole 7a. The through-hole 7a is provided inside the microphone capsule case 2. If that side of the first microphone 1a on which the first sound hole 3a is provided is designated as the front (F) side and the other side is designated as the back (B) side, the through-hole 7a starts from the back (B) side of the first microphone 1a, runs along the side wall of the microphone capsule case 2, and leads to the second sound hole 3b of the second microphone 1b. Consequently, the through-hole 7a runs from the rear face of the first microphone 1a (that side of the first diaphragm 5a which is farther from the first sound hole 3a) and connects with the outside world through the second sound hole 3b at the back face of the microphone capsule case 2. This makes it possible to give directivity to the first microphone 1a.

FIG. 8B shows a configuration example which has the same effect as FIG. 8A.

In this example, a through-hole 7b runs across almost the center of the second microphone 1b along its axis from the back side of the first microphone 1a to the second sound hole 3b. Thus, compared to the through-hole 7a described with reference to FIG. 8A, since the through-hole 7b can be installed linearly, this configuration can improve frequency characteristics of the first microphone. On the other hand, however, a second diaphragm 61 of the second microphone 1b has a special shape and differs in vibration characteristics from the first diaphragm 5. This may degrade vibration suppression characteristics.

### Fourth Embodiment

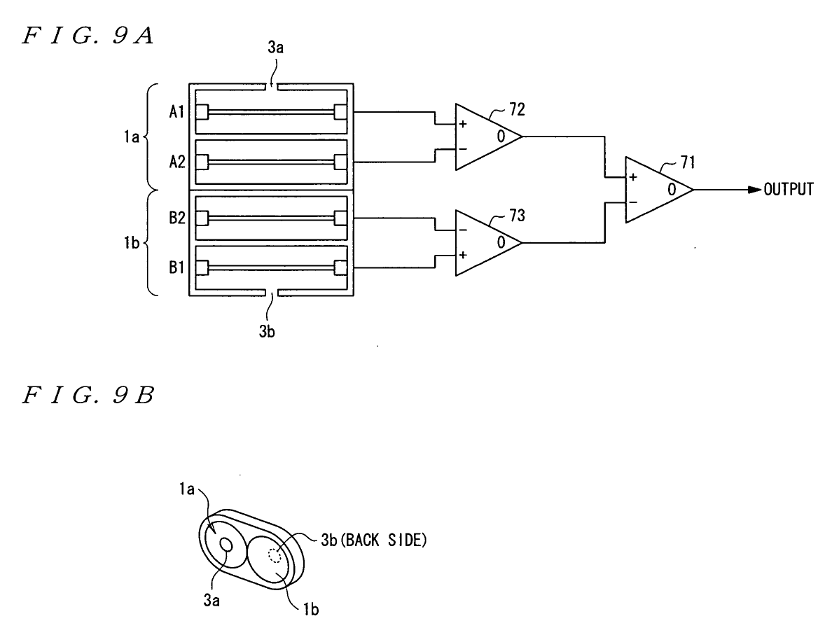

Next, a microphone system according to a fourth embodiment of the present invention will be described with reference to FIGS. 9A and 9B.

FIGS. 9A and 9B are diagrams showing configurations of the microphone system according to the fourth embodiment of the present invention. FIG. 9A is a sectional view and circuit diagram while FIG. 9B is a perspective view showing another configuration. This embodiment is a directional microphone system as in the case of the third embodiment.

In FIG. 9A, the first microphone 1a and second microphone 1b have the same configurations respectively as the corresponding ones according to the first embodiment.

As shown in FIG. 9A, the first microphone 1a and second microphone 1b are stacked along the same axis forming a cylindrical shape, i.e., they are coupled rigidly or formed integrally, being placed back to back. The first sound hole 3a is provided in the front face of the first microphone 1a and the second sound hole 3b is provided in the front face of the second microphone 1b. The first microphone 1a and second microphone 1b face in opposite directions. Outputs from the first microphone 1a and second microphone 1b are entered, respectively, in differential circuits 72 and 73, whose outputs are then entered in the differential circuit 71.

The first microphone 1a has a microphone A1 and microphone A2 while the second microphone 1b has a microphone B1 and microphone B2. The first microphone 1a and second microphone 1b are connected to the differential circuits 72 and 73, respectively. The output from the microphone A1 is connected to a positive input of the differential circuit 72 while the output from the microphone A2 is connected to a negative input of the differential circuit 72. Similarly, The output from the microphone B1 is connected to a positive input of the differential circuit 73 while the output from the microphone B2 is connected to a negative input of the differential circuit 73.

The differential circuits 72 and 73 are connected to positive and negative inputs of the differential circuit 71, respectively. Thus, with this system, the differential circuit 71 outputs the result of subtracting the output of the second microphone 1b (microphone B1 minus microphone B2) from the output of the first microphone 1a (microphone A1 minus microphone A2).

This makes it possible to give directivity to the microphone as a whole.

FIG. 9B shows another configuration example which has the same effect as FIG. 9A.

According to this example, the first microphone 1a and second microphone 1b are placed in opposite directions facing each other as in the case of the example described with reference to FIG. 9A, but they are placed next to each other in parallel rather than being stacked along the same axis forming a cylindrical shape.

This makes it possible to reduce the overall height of the system.

### Fifth Embodiment

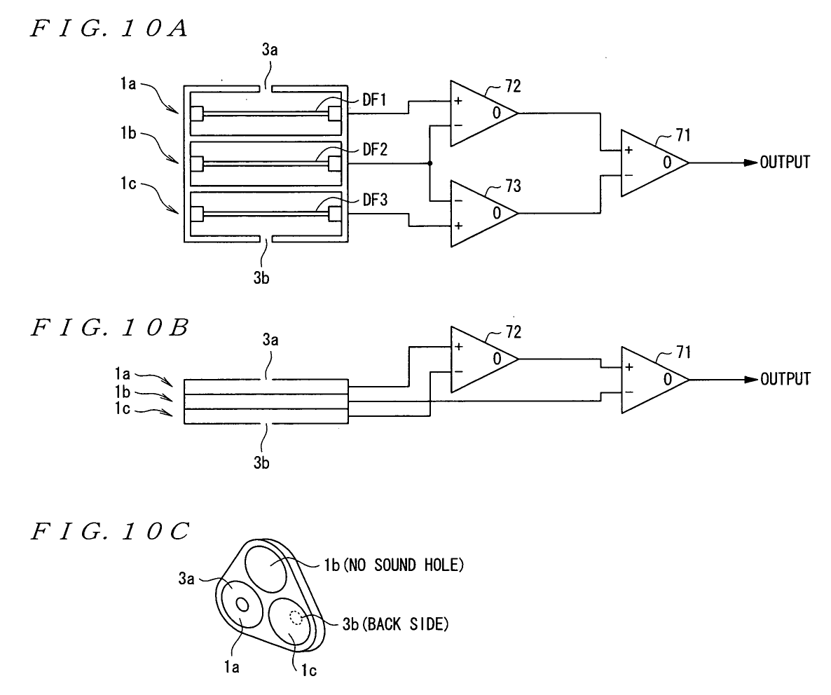

Next, a microphone system according to a fifth embodiment of the present invention will be described with reference to FIGS. 10A to 10C.

FIGS. 10A to 10C are diagrams showing configurations of a microphone system according to a fifth embodiment of the present invention. FIG. 10A is a circuit diagram, FIG. 10B is a circuit diagram showing another configuration, and FIG. 10C is a perspective view showing still another configuration. This embodiment is another directional microphone system according to the present invention, a multi-output microphone system.

As shown in FIG. 10A, this embodiment uses three microphones: a first microphone 1a, second microphone 1b, and third microphone 1c. The first and third microphones 1a and 1c have the same configuration as the first microphone 1a according to the first embodiment and the second microphone 1b has the same configuration as the second microphone 1b according to the first embodiment.

That is, the first microphone 1a has a first sound hole 3a, the second microphone 1b is completely enclosed without a sound hole, and the third microphone 1c has a sound hole 3b as is the case with the first microphone 1a. The first, second, and third microphones 1a, 1b, and 1c are coupled rigidly or formed integrally. They are stacked along the same axis, forming a cylindrical shape. The first microphone 1a has the first sound hole 3a in its front face and the third microphone 1c has the second sound hole 3b in its front face. They face in opposite directions. The second microphone 1b has an enclosed cylindrical shape.

The differential circuit 72 accepts output from the first microphone 1a at its positive input, and output from the second microphone 1b at its negative input. The differential circuit 73 accepts output from the third microphone 1c at its positive input, and output from the second microphone 1b at its negative input. Outputs from the differential circuits 72 and 73 are connected, respectively, to positive and negative inputs of the differential circuit 71, which then produces a differential output based on the two inputs.

Thus, the system outputs a differential signal resulting from (first microphone 1a minus second microphone 1b) minus (third microphone 1c minus second microphone 1b).

This makes it possible to give directivity to the microphone system as a whole.

FIG. 10B shows another circuit configuration example which has the same effect as FIG. 10A.

Again, the first, second, and third microphones 1a, 1b, and 1c are stacked along the same axis, the first microphone 1a and third microphone 1c have sound holes 3a and 3b, respectively, in opposite directions, and the second microphone 1b does not have a sound hole.

According to this embodiment, outputs from the first, second, and third microphones 1a, 1b, and 1c are entered in two differential circuits 71 and 72: the output from the first microphone 1a is entered in the positive input of the differential circuit 72 and output from the third microphone 1c is entered in the negative input of the differential circuit 72; the output from the differential circuit 72 is entered in the positive input of the differential circuit 71 and output from the second microphone 1b is entered in the negative input of the differential circuit 71; and the differential circuit 71 produces a differential output based on the two inputs.

Thus, the system outputs a differential signal resulting from (first microphone minus third microphone) minus second microphone.

This makes it possible to reduce the overall height of the system.

FIG. 10C is a still another circuit configuration diagram. As can be seen, the first, second, and third microphones 1a, 1b, and 1c are installed side by side in this example rather than being stacked along the same axis forming a cylindrical shape, which is the case with the previous example. They may be installed in such a way as to form a triangle. In this case, the first sound hole 3a of the first microphone 1a and second sound hole 3c of the third microphone 1c face in opposite directions. The second microphone 1b without a sound hole is mounted between the first microphone 1a and second microphone 1b. This also makes it possible to reduce the overall height of the system.

Thus, the technique according to the present invention makes it possible to implement a small, inexpensive microphone system which is impervious to extraneous vibration noise.

Embodiments of the microphone system according to the present invention has been described above, but the present invention is not limited to these embodiments and various modifications are possible without departing from the spirit and scope of the present invention.

1. A microphone system, comprising: a first microphone mechanism which has a sound hole for introducing sound; and a second microphone mechanism which is enclosed without a sound hole, wherein the first microphone mechanism and the second microphone mechanism are coupled rigidly or formed integrally.

2. The microphone system according to claim 1, wherein the first microphone mechanism and second microphone mechanism have approximately the same inner structure.

3. The microphone system according to claim 1, wherein a diaphragm installed in the second microphone mechanism is thinner, weaker in tension, or made of softer material than a diaphragm installed in the first microphone mechanism.

4. The microphone system according to claim 3, wherein the diaphragm installed in the second microphone mechanism has a single or multiple through-holes or the diaphragm itself has a mesh structure.

5. The microphone system according to claim 1, further comprising a differential circuit which outputs a differential signal based on output difference between the first microphone mechanism and the second microphone mechanism.

6. The microphone system according to claim 1, wherein both the first microphone mechanism and the second microphone mechanism comprise a diaphragm which receives external vibration and a back electrode which constitutes a microphone in conjunction with the diaphragm; output from the diaphragm of the first microphone mechanism and output from the back electrode of the second microphone mechanism are connected; and output from the back electrode of the first microphone mechanism and output from the diaphragm of the second microphone mechanism are connected.

7. The microphone system according to claim 1, wherein both the first microphone mechanism and the second microphone mechanism comprise a diaphragm which receives external vibration and a back electrode which constitutes a microphone in conjunction with the diaphragm; and electret films installed on the back electrodes of the first microphone mechanism and the second microphone mechanism are charged in opposite directions.

8. The microphone system according to claim 1, wherein both the first microphone mechanism and the second microphone mechanism comprise a diaphragm which receives external vibration and an electrode which constitutes a microphone in conjunction with the diaphragm; and if the first microphone mechanism has a back-mounted electrode, the second microphone mechanism has an electrode installed at the front, and conversely if the first microphone mechanism has a front-mounted electrode, the second microphone mechanism has an electrode installed at the back.

9. The microphone system according to claim 1, wherein both the first microphone mechanism and the second microphone mechanism comprise a diaphragm which receives external vibration and an electrode which constitutes a microphone in conjunction with the diaphragm; and the first microphone mechanism has another sound hole on the side of the diaphragm which does not have the sound hole.

10. A multi-microphone system, wherein two microphone systems according to claim 1 with the same or different sound holes are placed back to back or adjacent to each other in such a way that the respective sound holes will face in opposite directions, the multi-microphone system comprising a differential circuit which outputs a differential signal based on output difference between the two microphone systems.

11. A multi-microphone system, comprising: a first microphone mechanism which has a sound hole for introducing sound; a second microphone mechanism which is enclosed without a sound hole; and a third microphone mechanism which has a sound hole,
wherein the sound hole in the first microphone mechanism and the sound hole in the third microphone mechanism are placed in such a way as to face in opposite directions,
the second microphone mechanism is placed between the first microphone mechanism and the third microphone mechanism, and the first, second, and third microphone mechanisms are either coupled rigidly or formed integrally, being placed back to back or adjacent to each other, and
the microphone system further comprises a first differential circuit which outputs a differential signal based on output difference between the first microphone mechanism and the second microphone mechanism,
a second differential circuit which outputs a differential signal based on output difference between the third microphone mechanism and the second microphone mechanism, and
a third differential circuit which outputs a differential signal based on output difference between the first differential circuit and the second differential circuit.
